(19) United States
(12) Patent Application Publication
(10) Pub. No.: US 2005/0006640 A1
(43) Pub. Date: Jan. 13, 2005

(54) Polymer-based memory element

(76) Inventors: Warren B. Jackson, San Francisco, CA (US); Sean Zhang, Sunnyvale, CA (US); Craig M. Perlov, San Mateo, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/608,791

(22) Filed: Jun. 26, 2003

(51) Int. Cl. H01L 47/00

(52) U.S. Cl. 257/40; 257/5

(57) ABSTRACT

Fuse-type and antifuse-type semiconducting-organic-polymer-film-based memory elements for use in memory devices are disclosed. Various embodiments of the present invention employ a number of different techniques to alter the electrical conductance or, equivalently, the resistance, of organic-polymer-film memory elements in order to produce detectable memory-state changes in the memory elements. The techniques involve altering the electronic properties of the organic polymers by application of heat or electric fields, often in combination with additional chemical compounds, to either increase or decrease the resistance of the organic polymers.

### TECHNICAL FIELD

The present invention relates to electronic memories and memory elements and, in particular, to organic-polymer-based fuse-type and antifuse-type electronic memory elements.

### BACKGROUND OF THE INVENTION

For many years, the electronic memory devices commonly employed in computer systems for non-volatile data storage have included magnetic disks and tapes, for mass data storage, and various solid-state, chip-based memories, such as flash memory, for non-volatile storage of smaller quantities of data. The capacities of flash memories and other solid-state memories have continued to increase with the continued advances in photolithography and chip-manufacturing techniques. However, current and projected future needs for increased capacity, ease and economy of manufacturing, and decreasing power for operation are outstripping the rate of improvements in traditional, solid-state memory devices.

Recently, alternative types of non-volatile memories have been proposed, and numerous new types of non-volatile memories have been produced. Increasingly promising new types of non-volatile memories are based on semiconducting and conducting organic polymer films. FIG. 1 illustrates a small, rectangular region of a two-dimensional array of organic-polymer-based memory elements. The two-dimensional array of memory elements comprises a first set of parallel signal lines 102-111, a second set of parallel, conductive signal lines 112-118 oriented roughly perpendicularly to the first set of parallel, conductive signal lines 101-111, and semiconducting-organic-polymer-based memory elements, such as memory element 120, lying between the regions of overlap between the conductive signal lines. A two-dimensional memory-element array is manufactured by forming one set of conductive signal lines on a substrate, such as glass or plastic, then depositing one or more organic polymer films on top of the set of parallel, conductive signal lines, and finally forming a second set of parallel, conductive signal lines roughly orthogonal to the first set of signal lines on top of the deposited, organic polymer films. Photoresist functionality may be engineered into one or more of the organic polymer films, or separate photoresist layers may be deposited, so that those portions of the deposited organic polymer films outside of the regions of overlap between the two sets of conductive signal lines may be removed by exposing the two-dimensional array to light and solvents, in the same way that photolithographic techniques are employed for etching and removing layers during standard chip-manufacturing processes. Two-dimensional memory-element arrays, such as the array shown in FIG. 1, may be stacked on top of one another, with interleaving dielectric layers, in order to produce compact, three-dimensional memory-element lattices. The use of organic polymer films provides manufacturing and cost efficiencies.

FIGS. 2A-B illustrate one type of semiconducting-organic-polymer-based memory element. In FIGS. 2A-B, a single memory element within the overlap region of two non-collinear conductive signal lines is shown. In FIG. 2A, the semiconducting-organic-polymer-based memory element 202 comprises two different, adjoining semiconductor-film layers 204 and 206 that together produce a pn-junction-type diode that allows current to readily flow between the two conducting signal lines 208 and 210 in one direction, but resists current flow in the other direction. The intact, semiconducting-organic-polymer-film memory element 202 shown in FIG. 2A represents a first memory state. A second memory state is produced by passing a sufficiently high current through the memory element to physically disrupt and vaporize the two-component organic-polymer-based diode, as shown in FIG. 2B. Once the memory element is vaporized, as shown in FIG. 2B, no current passes between the two conductive signal lines unless extremely high voltage is applied. Thus, each memory element in an array of two-component organic-polymer-based memory elements may be in a low resistance state or an insulating state. An array featuring the type of memory elements illustrated in FIGS. 2A-B is a write-once memory, because once the memory element is vaporized, and placed into the insulating state, it cannot be returned to the low resistance state. The state of a memory element is easily determined by applying a voltage to, or directing current into, the appropriate conductive signal line and determining whether the applied voltage or current is detectable on the other conductive signal line. This type of memory element is referred to as an organic polymer fuse.

A similar, second type of memory element also consists of two organic polymer films that form a junction diode. However, in the second type of memory element, a high voltage may be applied to change the state of the memory element from electrically conducting to a state of high resistance. Again, the change of state is generally irreversible, but, rather than requiring complete physical destruction of the memory element, the organic polymer fuse is transformed by high voltage from a low resistivity state to a high resistivity state.

Although both types of organic polymer-fused memory elements have been incorporated into memory devices, various drawbacks and deficiencies have been identified. First, a relatively large amount of electrical power is required to change the state of a memory element of the first, above-described type. In memory devices using the first-described type of memory element, vaporization of memory elements may produce a large amount of secondary destruction of fragile signal lines and adjacent memory elements. Not only is a large amount of power required to vaporize the memory elements, but a relatively large amount of time is necessary for the bulk physical degradation and dislocation of the organic polymer films. Both types of memory elements are fuse-type memory elements that are irreversibly transformed from conductive to high resistance states, very much like the fuse in the electrical wiring of a house can be blown by a current surge. In certain applications, it would be desirable to transition the state of a memory element in the opposite direction, from a high resistance state to a low resistance state. Moreover, in many applications, reversible changes are desirable, to allow the memory to be erased and re-written multiple times. For these reasons, designers, manufacturers, and users of electronic devices that include non-volatile memories have recognized the need for additional types of organic-polymer-film-based memory elements.

### SUMMARY OF THE INVENTION

Various embodiments of the present invention provide both fuse-type and antifuse-type organic-polymer-film-based memory elements for use in memory devices. The various embodiments of the present invention employ a number of different techniques to alter the electrical conductance or, equivalently, the resistance, of organic-polymer-film memory elements in order to produce detectable memory-state changes in the memory elements. The techniques involve altering the electronic states of organic polymers by application of heating, cooling, electrical potentials, electrical current, chemical potentials, electrochemical potentials, electromagnetic radiation, or magnetic fields to either increase or decrease the resistance of the organic polymers.

### BRIEF DESCRIPTION OF THE DRAWINGS

FIG. 1 illustrates a small, rectangular region of a two-dimensional array of organic-polymer-based memory elements.

FIGS. 2A-B illustrate one type of semiconducting-organic-polymer-based memory element.

FIGS. 3A-C illustrate a conductive organic polymer.

FIGS. 4A-B illustrate doping of a semiconductor organic polymer, according to initial theories.

FIG. 5 schematically illustrates production of solitons.

FIG. 6 illustrates production of polarons and bipolarons.

FIG. 7 schematically illustrates a number of different possible types of solitons and bipolarons that can be produced in an organic polymer by various nucleophilic and electrophilic chemical entities.

FIGS. 8A-B show various different, well-known conductive polymers.

FIG. 9 illustrates a general approach to fashioning new and desirable organic-polymer-based memory elements.

FIG. 10 illustrates one class of fuse-type organic-polymer-based memory elements that represents a number of embodiments of the present invention.

FIG. 11 illustrates a second class of antifuse-type organic-polymer-based memory elements that represents a second set of embodiments of the present invention.

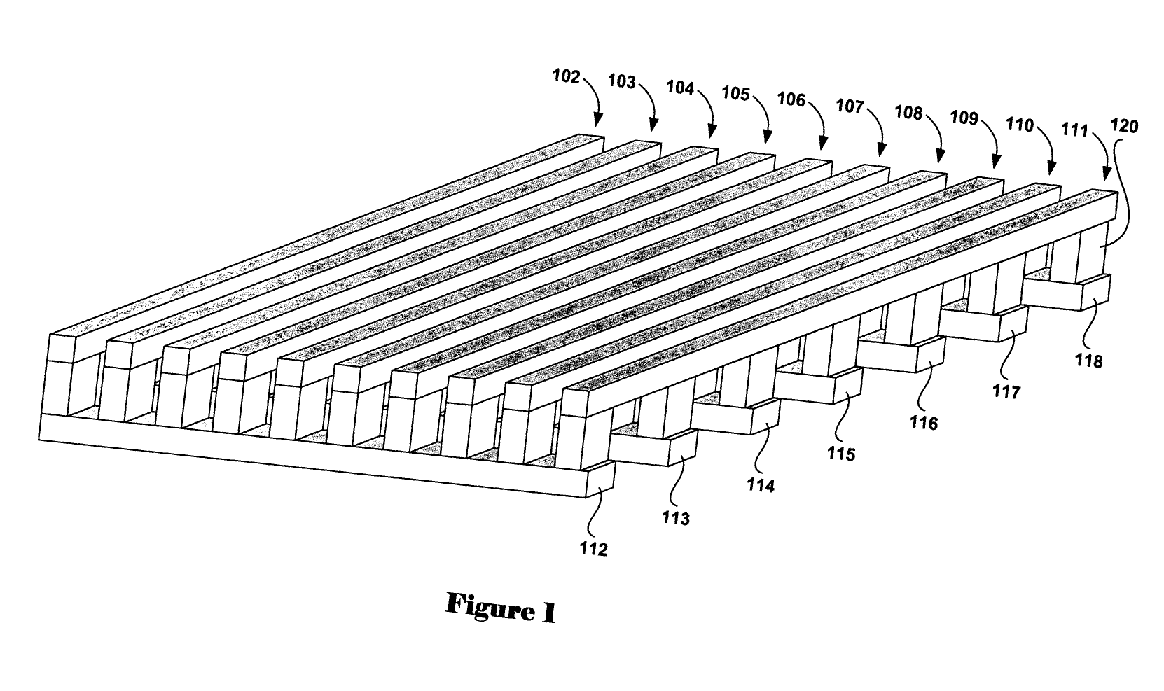

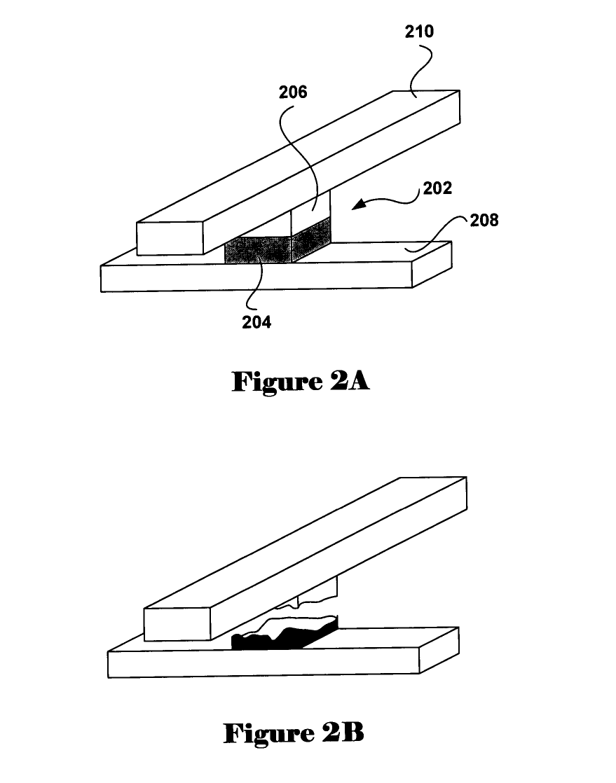

### DETAILED DESCRIPTION OF THE INVENTION

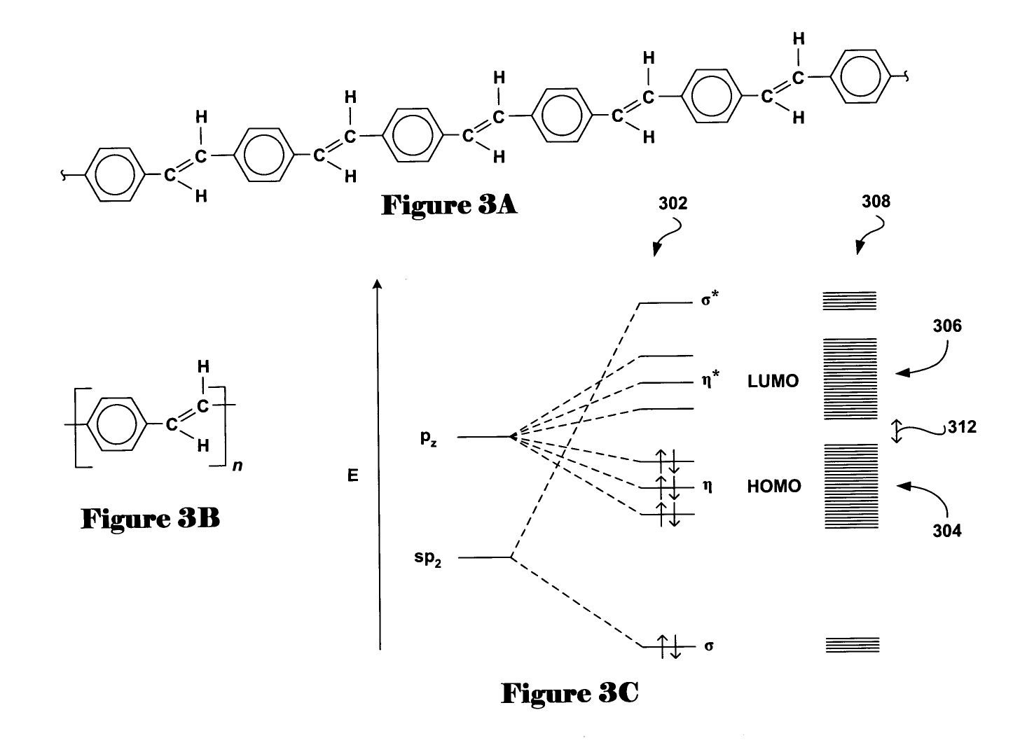

Most synthetic and naturally occurring organic polymers are insulators. During the past 30 years, large research efforts have been devoted to developing conductive organic polymers for use in a wide variety of different electrical applications. Currently, a rather large number of highly conductive organic polymers are known, and the research efforts undertaken to identify and synthesize conductive polymers have provided great insight into the nature of conductive organic polymers. FIGS. 3A-C illustrate a conductive organic polymer. FIG. 3A shows a chemical notational representation of the conductive organic polymer polyphenylenevinylene. The polyphenylenevinylene polymer is a long chain of repeating phenylenevinylene monomer subunits. A segment of the chain is shown in FIG. 3A. Polymer chains may extend for tens to hundreds to even thousands of monomer subunits. Naturally occurring biopolymers, such as DNA, may extend to millions of covalently linked subunits. The polyphenylenevinylene polymer, notationally represented in FIG. 3A, can be more compactly represented by the notation shown in FIG. 3B, where a single monomer subunit is shown within brackets, with the subscript n indicating that the monomer subunit repeats along the polymer chain.

In FIG. 3C, the energy levels of the molecular orbitals for a phenylenevinylene monomer subunit are shown in a first column 302. The molecular orbitals include sp₂ orbitals and p_{z} orbitals associated with double-bonded carbons. The various ways in which molecular orbitals are populated by valence electrons corresponds to molecular quantum states, each quantum state having a particular π

energy. In general, in the ground-state electronic configuration, the lower-energy molecular orbitals are occupied by two electrons with paired spins, while the higher-energy quantum states are unoccupied. The π orbitals associated with carbon-carbon double bonds are relatively closely-spaced in energy, and are the highest-energy molecular orbitals occupied by electrons in the ground state. They are referred to as highest occupied molecular orbitals (“H OMO”). Higher-energy antibonding π orbitals are also closely spaced in energy, and represent the lowest unoccupied molecular orbitals (“LUMO”).

In a conductive polymer, such as the polyphenylenevinylene polymer shown in FIG. 3A, alternating single and double bonds along the carbon backbone of the polymer produce dense, closely spaced bands of π orbitals 304 and π* antibonding orbitals 306 when the molecular orbitals for the polymer are plotted with respect to energy, as in column 308 of FIG. 3C. The gap in energy between the HOMO π orbitals and the LUMO π* antibonding orbitals 312 is relatively narrow, just as in an inorganic semiconductor, such as silicon or galium arsenide. The LUMO orbitals together represent a conductive band. Initially, it was thought that electrons that can be promoted into the LUMO orbitals become de-localized along the molecule, and can carry current. Promotion of electrons from HOMO orbitals to LUMO orbitals also leaves holes in the HOMO orbitals, which were also thought to carry current, but in a direction opposite from the current thought to be carried by delocalized electrons in conductive-band orbitals. According to the initial theory of organic polymer conduction, it was thought that, n some cases, with sufficiently long polymer-chain lengths, the HOMO and LUMO bands may overlap, producing metal-like conductivity in the polymer. However, when the valence and conduction fans do not overlap, as in a metal, but are separated by a small energy gap, as in a semiconductor, the polymer may be doped with appropriate doping agents in order to populate the conductive band with electrons and the valence band with holes, in order to transform the semiconductor polymer into a conducting polymer.

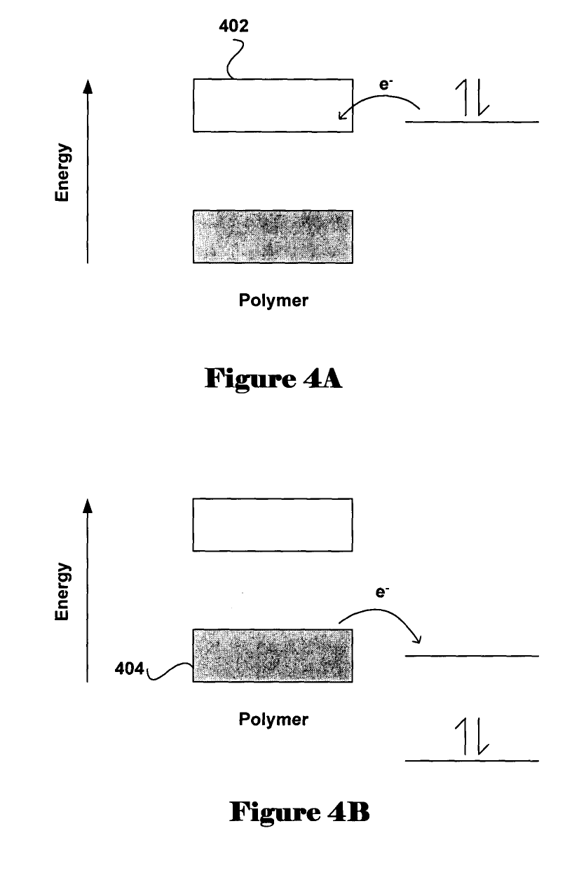

FIGS. 4A-B illustrate doping of a semiconductor organic polymer, according to initial theories. As shown in FIG. 4A, an electron-donating chemical entity may contribute electrons to an unfilled molecular orbital in the conductive band 402 of a semiconductor polymer, thus producing delocalized, conductive-band electrons that can carry current. Similarly, as shown in FIG. 4B, an electron-accepting chemical entity can extract electrons from the valence band 404 of a semiconductive polymer in order to produce holes in the valence band that can carry current in a direction opposite from current carried by de-localized electrons in the conductive band.

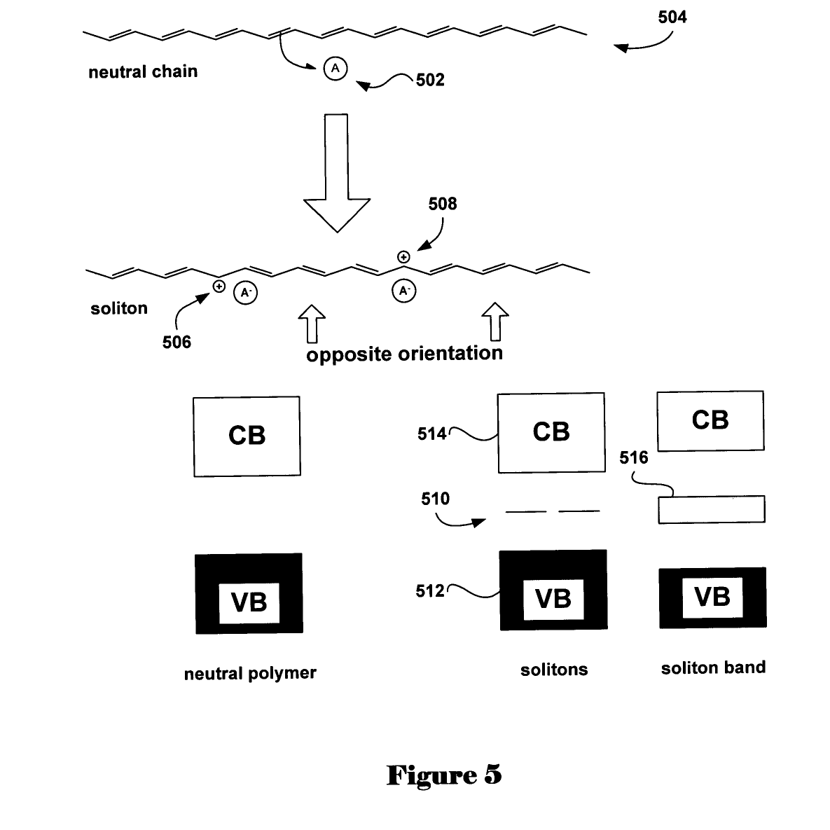

Unlike in inorganic semiconductors, the main current carriers in organic polymers are currently thought to most commonly be solitons and bipolarons. FIG. 5 schematically illustrates production of solitons. As shown in FIG. 5, an electrophilic entity “A” 502 may extract an electron from a neutral organic polymer 504 to produce carbocations 506 and 508 within the energy gap between the valence band 512 and the conduction band 514 of the organic polymer. Because of resonance of alternating single and double bonds, solitons are de-localized over 12 to 15 backbone carbon atoms. In a conjugated polymer, interleaved double and single bonds can rapidly interchange without requiring displacement of atoms. Thus, a greater number of quantum states closely spaced in energy are possible, leading to rapid double-bond/single-bond inversion. Solitons generally arise from either empty molecular orbitals introduced by removal of electrons or fully occupied, spin-paired orbitals introduced by addition of electrons. A number of de-localized solitons within an organic polymer produces a soliton band of electronic states 516 that can widen sufficiently to span the energy gap between the valence band 512 and the conduction band 514 to produce metal-like conductance.

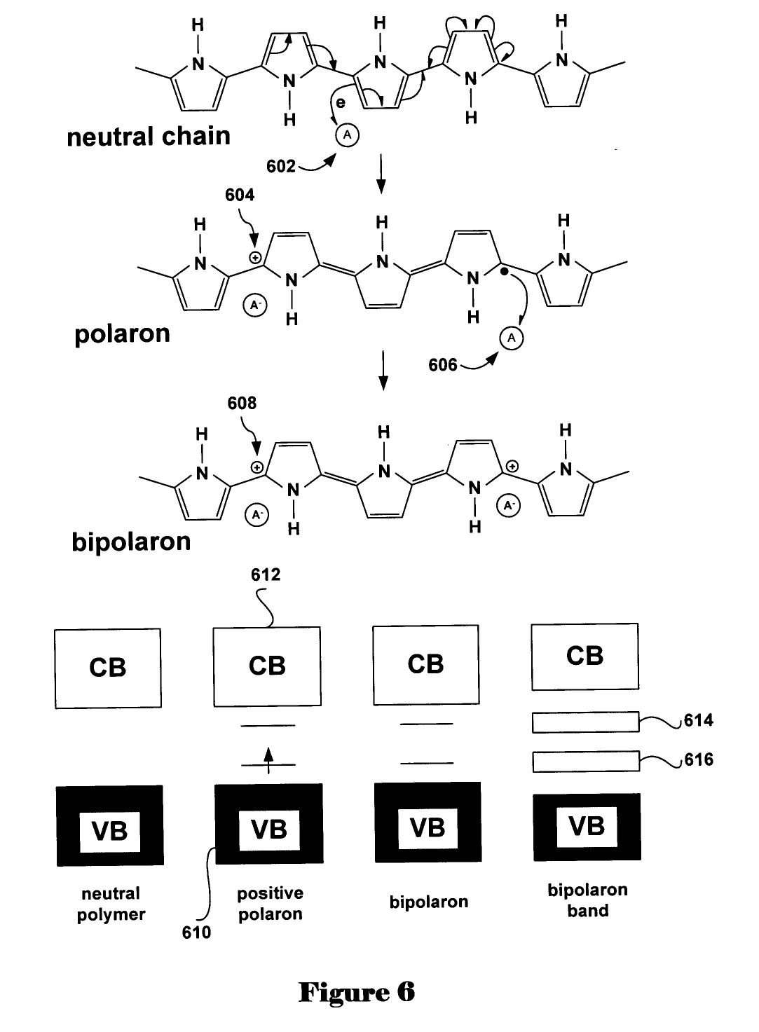

FIG. 6 schematically illustrates production of polarons and bipolarons. As shown in FIG. 6, an electrophilic entity “A” 602 can extract an electron from a neutral organic polymer to produce a radical cation 604 referred to as a “polaron.” Extraction of a second electron by a second electrophilic entity 606 produces a bipolaron carbodication 608. As also shown in FIG. 6, the polaron and bipolaron states introduce molecular orbitals with energies that fall into the energy gap between the valence band 610 energies and conduction band 612 energies for the polymer. Unlike solitons, polarons and bipolarons are characterized by partially-filled molecular orbitals. When a sufficient number of bipolarons are produced in the polymer, the two bipolaron bands 614 and 616 begin to fill the energy gap between the valance band 610 and conductive band 612, eventually spanning the energy gap to produce metal-like de-localization and conductance.

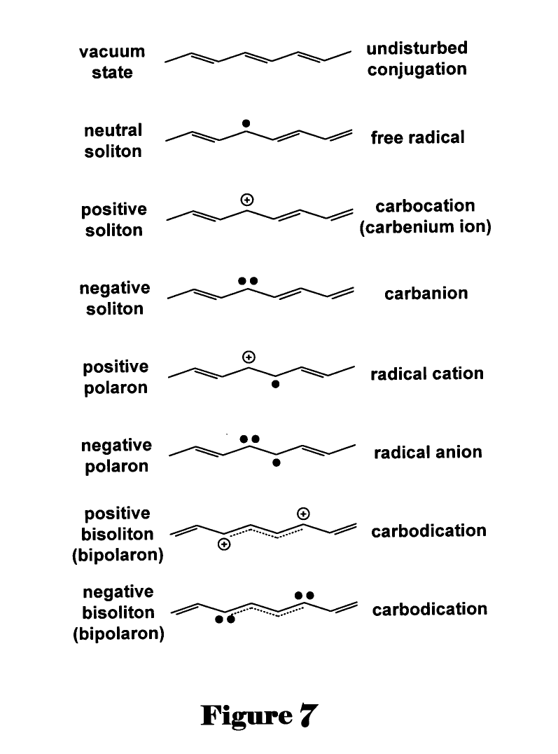

FIG. 7 schematically illustrates a number of different possible types of solitons and bipolarons that can be produced in an organic polymer by various nucleophilic and electrophilic chemical entities. Thus, the main charge carriers in many conductive organic polymers are believed to be solitons and bipolarons, rather than conduction-band electrons and valence-band holes, as in metals and inorganic semiconductors.

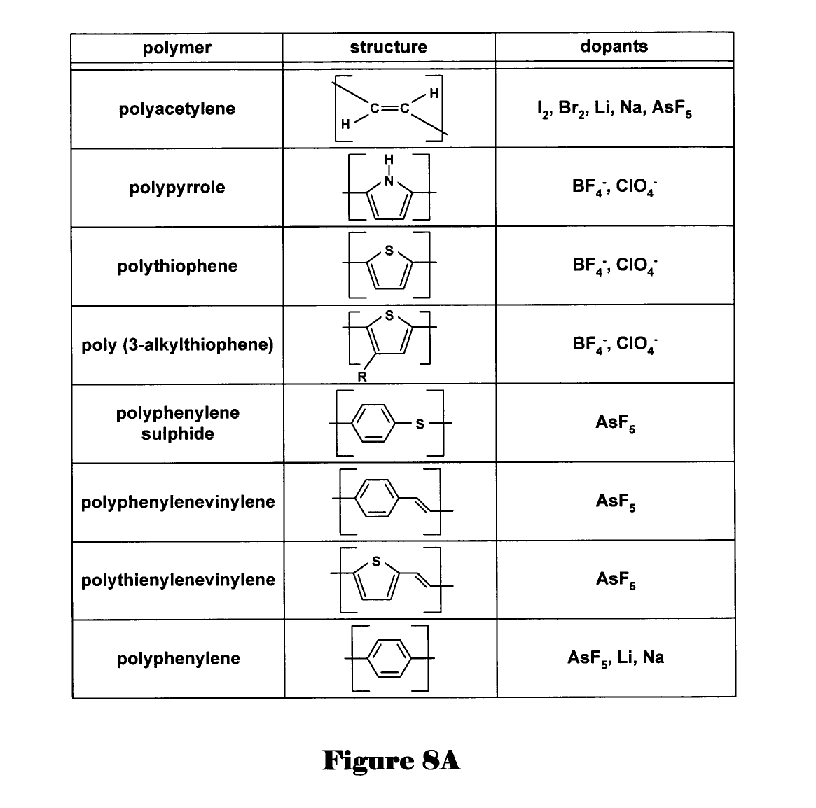

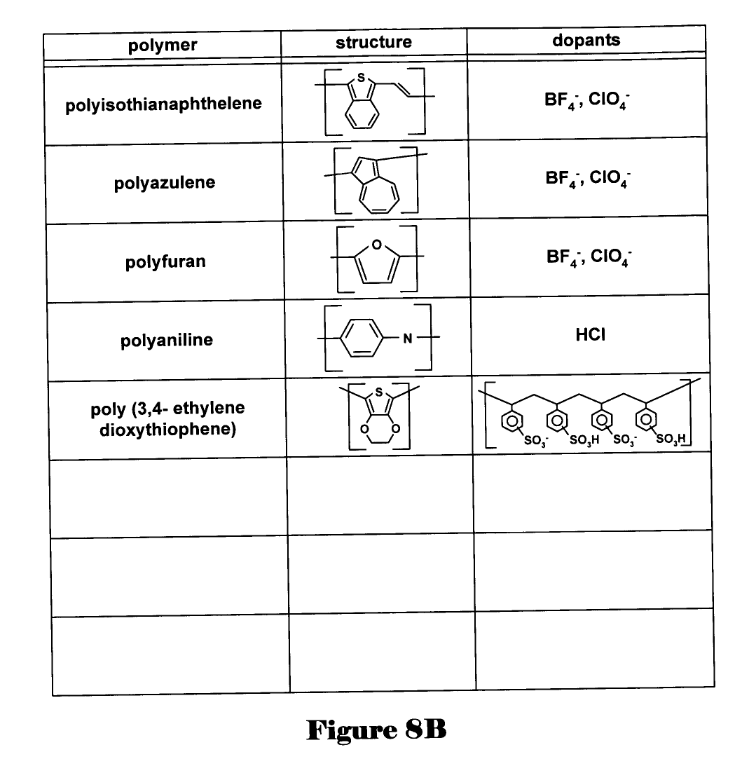

FIGS. 8A-B show various different, well-known conductive polymers. For each conductive polymer, FIGS. 8A-B show the polymer name, the monomer subunit structure, and one or more dopants that are employed to produce a conductive electronic state in the polymer, as described above.

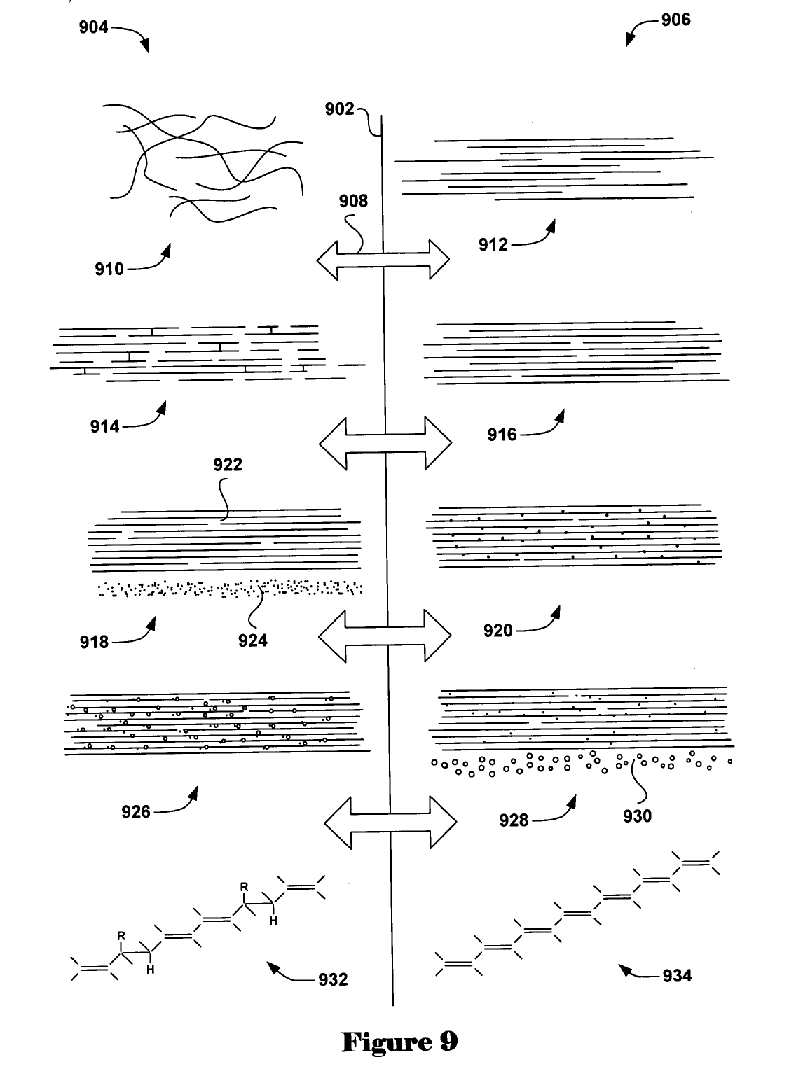

An understanding of the mechanisms by which current is carried in organic polymers, coupled with an awareness of the types of improvements to organic-polymer-based memory elements that would be desirable to ameliorate the disadvantages mentioned above, and provide greater flexibility and finer tuning of conductivity states by which memory states are physically implemented, motivates various embodiments of the present invention. A general approach to fashioning new and desirable organic-polymer-based memory elements is illustrated in FIG. 9. FIG. 9 is divided into two vertical sections by a central, vertical line 902. The organic-polymer-film states illustrated in the left-hand portion of FIG. 9 904 represent high resistance or weakly conducting states, and the organic-polymer-film states illustrated in the right-hand portion of FIG. 9 906 represent conducting or low resistance states. Transformation of a high resistance state to a low resistance state, or the reverse transformation of a low resistance state to a high resistance state, as indicated by the double-headed arrows, such as double-headed arrow 908, constitute switching of a memory element from a first memory state to a second memory state. In a physical device, for example, the low resistance state may be used to represent the binary memory state “1” or ON, while the other high resistance state may represent the binary memory state “0” or OFF. Of course, an opposite convention may be employed. The two states need to be readily differentiable by, for example, applying a modest voltage or current to one signal line of a memory element and attempting to detect the applied voltage or current on the other signal line of the memory element.

A first type of memory-state transition is illustrated in paired states 910 and 912 in FIG. 9. In state 910, the individual polymers within an organic polymer film are relatively disordered, and not aligned with one another. In such a disordered state, there is little opportunity for inter-polymer-chain electron de-localization, and it has been found that disordered states, such as disordered state 910 shown in FIG. 9, are less conductive, or, equivalently, exhibit higher resistance, than ordered, aligned states, such as state 912 shown in FIG. 9. In the aligned state 912, π orbitals of different polymer chains may overlap with one another to produce inter-chain delocalization and greater conductivity. Thus, a first new type of memory element and mechanism for changing the state of the memory element that represent one embodiment of the present invention is an organic-polymer-based memory element that, when exposed to heat, an electrical field, or possibly to a change in chemical environment through diffusion of a solvent, dopant molecules, or other chemical entities, can transition from a disordered state to an ordered state, in which the polymer chains are relatively well aligned with one another, or can change from an ordered state to a disordered state. In certain cases, the transition may be irreversible, similar to the process by which proteins are denatured by heat. In other cases, the transition may be reversible. For example, certain organic polymers transition between mostly trans double bonds to mostly cis double bonds when the temperature is lowered, and return to mostly trans double bonds when the temperature is again raised.

A second type of organic-polymer-based memory element and mechanism for changing the memory state of the second type of memory element are illustrated by the paired states 914 and 916 in FIG. 9. In the high resistance state 914, chemical entities have been introduced into the film that break polymer chains and/or produce cross-links between polymer chains. An example cross-linking and chain-breaking chemical entity is the thiophene monomer introduced as a reactant into a polythiophene film. Many reactive radical initiators or cross-linking agents might be employed. In many cases, the transition from the low resistance state 916 to the chain-fractured and cross-linked state 914 is irreversible. However, reversible cross-linking and chain-break repair are possible.

Yet another new type of organic-polymer-based memory element and a mechanism for switching between low resistance and high resistance memory states are provided by the state pair 918 and 920 in FIG. 9. In the high resistance state 918, the organic polymer film 922 is distinct from an additional layer of dopant entities 924, with the dopant entities 924 unable to introduce electrons into, or extract electrons from, polymer chains, and therefore unable to produce molecular orbitals that span the energy gap between the valence band and conduction band of the polymer. Application of an electrical, chemical, or electrochemical potential across the memory element drives the dopant entities into the polymer film to effect the low resistance state 920. Similarly, application of an electrical, chemical, or electrochemical potential to the low resistance state 920 may drive the dopant entities back out from the polymer film to produce the high resistance state 918. The dopant entities may, include electrophilic and nucleophilic reagents, oxidizing and reducing agents, and other chemical entities that introduce molecular orbital with energies spanning the valence and conduction bands into the polymer.

Yet another new organic-polymer-based memory element and method for switching between low resistance and high resistance memory states are illustrated by the high resistance and low resistance state pair 926 and 928 in FIG. 9. In the high resistance state, chemical entities, represented, in FIG. 9 by unfilled circles, that can react with doping entities to decrease the doping efficiencies of the doping entities, or that can react directly with the organic polymer to counteract the effect of the dopant molecules, are present within the organic polymer film. Application of an electrical, chemical or electrochemical potential to the polymer film may drive the dopant-inhibiting entities out from the organic polymer film into a distinct layer 930. The absence of dopant inhibitors allows the remaining dopant entities to produce the molecular orbitals that span the energy gap between the valence and conductive bands within the organic polymer that, in turn, produce low resistance. Again, as with the previous low-resistance/high-resistance state pair, transition from the high resistance 926 to the low resistance state 928 may be reversible. Examples of dopant inhibitors include various amines, such as methylamine, dimethylamine, ethanolamine, hydroxylamine, and others. Such compounds can neutralize dopant acids, such as sulphonic acids. In a related memory element, dopant-enhancing chemical entities may be employed to produce low resistance, when present, and high resistance, when absent.

Yet another new type of organic-polymer-based memory element and method for switching between high resistance and low resistance memory states are provided by the high resistance and low resistance state pair 932 and 934 in FIG. 9. In the high resistance state 932, a reactive compound that can reduce a carbon-carbon double bond by adding protons or functional groups across the double bond to produce sp₃ single-bonded carbons in place of the sp₂ double-bonded carbons has disrupted the pattern of alternating double and single bonds along the organic polymer. In the low resistance state 934, the added functional groups are removed to restore the alternating single and double carbon bonds along the backbone of the organic polymer. In certain cases, the transition from the low resistance state 934 to the high resistance state 932 is irreversible, although, in other systems, the transition may be reversible. A particularly attractive example would be hydrogenation of double bonds by hydrogen gas or by a proton-donating electrophile.

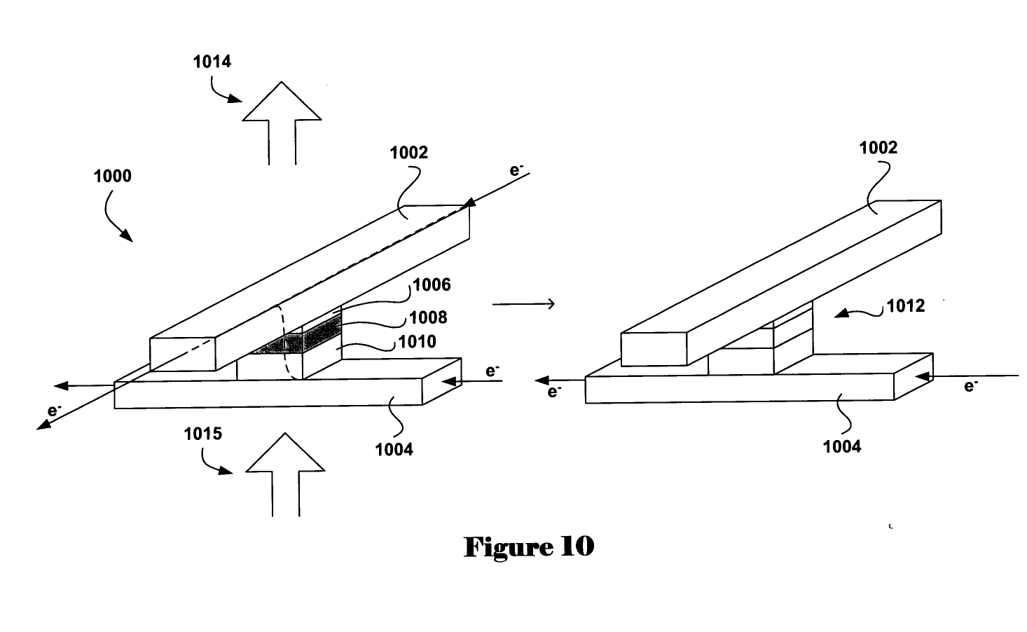

FIG. 10 illustrates one class of fuse-type organic-polymer-based memory elements that represents a number of embodiments of the present invention. In general, the memory element of these embodiments comprises the overlap region between a first conducting signal line 1002 and a second conducting signal line 1004. The memory element is generally composed of two different organic polymer films 1006 and 1008, and may include may include an additional one or more layers 1010 above, below, or interleaving the organic polymer films. In the class of memory elements illustrated in FIG. 10, an initial low resistance state of one or more of the organic polymer films 1006 and 1008 may be transformed, either reversibly or irreversibly, to a high resistance state 1012 by applying a chemical, electrical, or electrochemical potential across the memory element, as indicated by the large arrows 1014-1015 in FIG. 10. Additionally, electromagnetic radiation, magnetic fields, electrical current, or other types of transition facilitating agents may employed to switch the memory state of a memory element, depending on the type of memory element and types of additional chemical entities, such as dopants and reactants, included within or adjacent to the organic polymer. In the low resistance state 1000, the first and second conducting signal lines 1002 and 1004 are electrically interconnected by the memory element comprising layers 1006 and 1008 and, in certain cases, one or more optional layers 1010. Following application of a chemical, electrical, or electrochemical potential, or electromagnetic radiation, magnetic fields, electrical current, or other types of state-transition-facilitating agents to or across the memory element, the memory element 1012 transitions to a high resistance state, disconnecting the electrical connection between the first conducting signal line 1002 and the second conducting signal line 1004.

The fuse-type memory element may include an organic polymer film with the polymers stretched or otherwise aligned to produce a relatively conductive film. This low resistance state may be switched to a high resistance state by cooling or heating, depending on the chemical nature of the polymers, or by applying an intense voltage potential to denature the aligned polymer chains, possibly through a secondary heating effect. Such transitions may be reversible, with application of heating or cooling to a high resistance state producing an aligned-polymer-chain low resistance state. In certain cases, application of an electrical field may serve to align electrically charged polymers to change a high resistance state to a low resistance state. Additionally, the transition between a disordered, high resistance state and an ordered, low resistance state may be reversibly driven by applying a chemical, electrical, or electrochemical gradient to drive dopants, ions, solvents, and other chemical entities into the organic polymer film from a third layer and to drive the chemicals back out from the organic polymer film into the third layer. In some cases, presence of dopants, ions, and other chemical entities may facilitate alignment in ordering of polymer chains, while, in other cases, the presence of chemical entities may serve to produce disordering and misalignment.

In another embodiment, cross-linking and/or chain-breaking agents may be included within the organic polymer film. Application of one or more state-transition-facilitating agents across or to the memory element may activate the cross-linking and/or chain-breaking compounds to react with the polymer chains in order to disrupt inter-chain electron de-localization and increase the resistivity of the organic polymer film. Such memory-state transitions tend to be irreversible, but, in certain cases, the presence of a second small-molecule compound and application of an oppositely oriented state-transition-facilitating agent may facilitate polymer-chain repair and cross-link disruption. The cross-linking and/or chain-breaking compounds may be included either within the organic polymer film, or may be included in a separate layer or medium and driven into the organic polymer film by means of application of state-transition-facilitating agent across or to the memory element.

In another embodiment, one or more additional layers within the memory element may contain dopant entities that, when driven into the organic polymer film by application of a state-transition-facilitating agent, produce the spanning electronic states within the polymer chains to increase conductivity, while application of an oppositely state-transition-facilitating agent may drive the dopant entities back out of the organic polymer film to increase the resistance of the memory element. In certain cases, the dopant entities may be directly included within the organic polymer film, and inactivated or deactivated by application of state-transition-facilitating agent across or to the memory element.

In another embodiment, dopant-inhibiting compounds or dopant-activating compounds may be driven into, or driven out from, an organic polymer layer to increase conductivity and to increase resistance, respectively, in order to switch the memory state. Again, the dopant-inhibiting or dopant-enhancing compounds may be included directly within the organic polymer film, and activated by application of one or more state-transition-facilitating agents across or to the memory element, or may be included in a separate layer and driven into, and out from, the organic polymer film by application one or more state-transition-facilitating agents across the memory element.

Finally, chemical entities that may add across carbon-carbon double bonds to disrupt the alternating single and double bond structure of conducting organic polymers may be included within the organic polymer film, and activated by application of one or more state-transition-facilitating agents across or to the memory element, or may be included in a third layer and driven into the organic polymer film via application of one or more state-transition-facilitating agents. Such reactions tend to irreversibly change a low resistance memory state to a high resistance memory state, although certain reversible systems may be implemented.

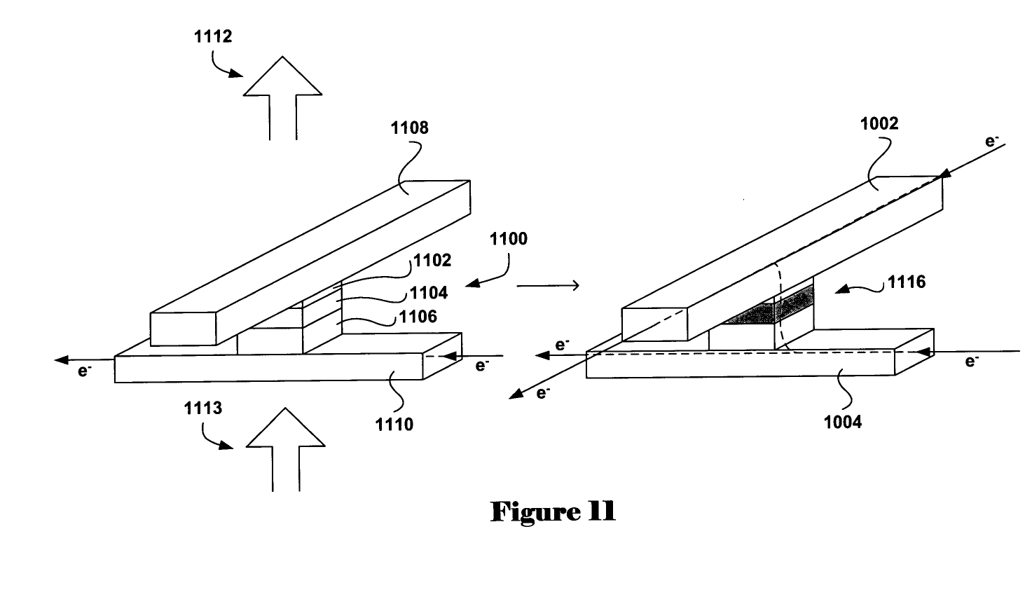

FIG. 11 illustrates a second class of antifuse-type organic-polymer-based memory elements that represents a second set of embodiments of the present invention. As shown in FIG. 11, the memory element 1100 generally includes two organic polymer films 1102 and 1104 and may include an additional one or more layers 1106 above, below, or interleaving the organic polymer films. The memory element is positioned in an overlap region between a first conducting signal line 1108 and a second conducting signal line 1110. Initially, the memory element is in a high resistance memory state. Application of one or more state-transition-facilitating agents to or across the memory element, represented in FIG. 11 by arrows 1112 and 1113, transforms at least one organic polymer film of a memory element to a low resistance state 1116, and, by doing so, electrically interconnects the first conductive signal line 1002 with the second conductive signal line 1004. The transition from a high resistance to a low resistance state may be irreversible or, in certain circumstances, may be reversible. A number of example embodiments are provided below.

The antifuse-type memory element may include an organic polymer film with the polymers disordered or otherwise misaligned to produce a relatively high resistivity film. This high resistance state may be switched to a low resistance state by cooling or heating, depending on the chemical nature of the polymers, or by applying a voltage potential or electrical field to align the polymer chains, possibly through a secondary heating effect. Such transitions may be reversible, with application of heating or cooling to a low resistance state producing a disordered, high resistance state. Additionally, the transition between a disordered, high resistance state and an ordered, low resistance state may be reversibly driven by applying a state-transition-facilitating agent to drive dopants, ions, solvents, and other chemical entities into the organic polymer film from a third layer and to drive the chemicals back out from the organic polymer film into the third layer. In some cases, presence of dopants, ions, and other chemical entities may facilitate alignment in ordering of polymer chains, while, in other cases, the presence of chemical entities may serve to produce disordering and misalignment.

In another embodiment, cross-linking and/or chain-breaking agents may be included within the organic polymer film. Application of one or more state-transition-facilitating agents across or to the memory element may deactivate cross-linking and/or chain-breaking compounds, force them from the organic polymer, or activate cross-link attacking and chain-breakage-repairing entities present in the organic polymer film.

In another embodiment, one or more additional layers within the memory element may contain dopant entities that, when driven into the organic polymer film by application of a state-transition-facilitating agent, produce molecular orbitals with energies that span the energy gap between the valence and conducting bands within the polymer chains to increase conductivity, while application of an oppositely state-transition-facilitating agent may drive the dopant entities back out of the organic polymer film to increase the resistance of the memory element. In certain cases, the dopant entities may be directly included within the organic polymer film, and inactivated or deactivated by application of state-transition-facilitating agent across or to the memory element.

In another embodiment, dopant-inhibiting compounds or dopant-activating compounds may be driven into, or driven out from, an organic polymer layer to increase conductivity and to increase resistance, respectively, in order to switch the memory state. Again, the dopant-inhibiting or dopant-enhancing compounds may be included directly within the organic polymer film, and activated by application of one or more state-transition-facilitating agents across or to the memory element, or may be included in a separate layer and driven into, and out from, the organic polymer film by application one or more state-transition-facilitating agents across the memory element.

Finally, chemical entities that may add across carbon-carbon double bonds to disrupt the alternating single and double bond structure of conducting organic polymers may be driven from the organic polymer film via application of one or more state-transition-facilitating agents. Although such reactions tend to irreversibly change a low resistance memory state to a high resistance memory state, certain reversible systems may be implemented.

Although the present invention has been described in terms of a particular embodiment, it is not intended that the invention be limited to this embodiment. Modifications within the spirit of the invention will be apparent to those skilled in the art. For example, as discussed above, both fuse-type and antifuse-type memory elements are intended to be within the scope of the present invention, with both reversible and irreversible memory-state transitions, depending upon the nature of the polymers and the nature of dopants and other chemical-entity facilitators of conductivity or increased resistance. As discussed above, various types of external gradients and potentials may be applied to the memory element to induce a switch from one memory state to another, including application of heat or cold, application of chemical, electrical, or electrochemical fields and/or gradients, application of voltage potentials to conductive signal lines, and other methods. As discussed above, various ionic and small-molecule chemical entities may be included directly within organic polymer films and activated by application of various gradients and potentials, or may be included in separate layers above, below, or interleaving between organic polymer films and driven into or out from the organic polymer films by application of various gradients and potentials. In certain applications, antifuse-type memory elements are desirable, because little power is consumed in transitioning the memory element from a high resistance to low resistance state. In other applications, fuse-type memory elements are preferred. The present invention allows either fuse or antifuse-type memory elements to be readily fabricated and manipulated. In certain applications, irreversible memory-state transitions are desirable. In other applications, reversible memory-state transitions are desirable, to allow a memory device to be erased and rewritten. The present invention provides both reversible and irreversible memory-state-transition memory elements. A wide variety of different conducting organic polymers, along with appropriate dopants and other ionic and small-molecule facilitators may be employed in the various memory elements that fall within the scope of the present invention.

The foregoing description, for purposes of explanation, used specific nomenclature to provide a thorough understanding of the invention. However, it will be apparent to one skilled in the art that the specific details are not required in order to practice the invention. The foregoing descriptions of specific embodiments of the present invention are presented for purpose of illustration and description. They are not intended to be exhaustive or to limit the invention to the precise forms disclosed. Obviously many modifications and variations are possible in view of the above teachings. The embodiments are shown and described in order to best explain the principles of the invention and its practical applications, to thereby enable others skilled in the art to best utilize the invention and various embodiments with various modifications as are suited to the particular use contemplated. It is intended that the scope of the invention be defined by the following claims and their equivalents:

1. An organic-polymer-based memory element comprising:
two overlapping conductive signals lines; and
at least one organic polymer layer within the region of overlap between the two signal lines, the organic polymer layer having at least two detectable memory states, transitions between which arise from one of changes in chemical bonds and changes in organic polymer doping.

2. The organic-polymer-based memory element of claim 1 wherein, in a first memory state, the organic polymer layer exhibits a first electrical resistivity and wherein, in the second memory state, the organic polymer layer exhibits a second electrical resistivity lower than the first resistivity, the organic-polymer-based memory element therefore an antifuse-type memory element.

3. The organic-polymer-based memory element of claim 2, wherein a memory-state transition is initiated by applying to the organic-polymer-based memory element one or more state-transition-facilitating agents selected from among:
heating;
cooling;
an electrical voltage potential;
a chemical potential;
an electrochemical potential;
electrical current;
electromagnetic radiation; and
a magnetic field.

4. The organic-polymer-based memory element of claim 3 wherein the organic polymer layer includes dopant chemical entities in addition to organic polymers, the dopant chemical entities inactive in the first memory state and active in the second memory state.

5. The organic-polymer-based memory element of claim 3 wherein the organic polymer layer is adjacent to an additional layer within the memory element, the additional layer including dopant chemical entities, a memory-state transition ensuing when dopant entities within the additional layer are driven into the organic polymer layer.

6. The organic-polymer-based memory element of claim 3 wherein organic polymers within the organic polymer layer are disordered, a memory-state transition ensuing when organic polymers within the organic polymer layer align with one another.

7. The organic-polymer-based memory element of claim 3 wherein the organic polymer layer is adjacent to an additional layer within the memory element, the organic polymer layer including cross-linking chemical entities, a memory-state transition ensuing when the cross-linking chemical entities are driven from the organic polymer layer into the additional layer.

8. The organic-polymer-based memory element of claim 3 wherein the organic polymer layer is adjacent to an additional layer within the memory element, the organic polymer layer including polymer-chain-breaking chemical entities, a memory-state transition ensuing when the polymer-chain-breaking chemical entities are driven from the organic polymer layer into the additional layer to restore broken polymer chains to an unbroken state.

9. The organic-polymer-based memory element of claim 3 wherein the organic polymer layer includes cross-linking chemical entities, a memory-state transition ensuing when the cross-linking chemical entities are driven from the organic polymer layer into the additional layer.

10. The organic-polymer-based memory element of claim 3 wherein the organic polymer layer includes polymer-chain-breaking chemical entities, a memory-state transition ensuing when the polymer-chain-breaking chemical entities are deactivated to restore broken polymer chains to an unbroken state.

11. The organic-polymer-based memory element of claim 3 wherein the organic polymer layer includes dopant chemical entities and dopant-inhibiting chemical entities in addition to organic polymers, a memory-state transition ensuing when the dopant entities within the organic polymer layer are deactivated.

12. The organic-polymer-based memory element of claim 3 wherein the organic polymer layer includes dopant chemical entities, wherein the organic polymer layer is adjacent to an additional layer within the memory element, the additional layer including dopant-inhibiting chemical entities, a memory-state transition ensuing when the dopant-inhibiting chemical entities are driven from within the organic polymer layer into additional layer.

13. The organic-polymer-based memory element of claim 3 wherein the organic polymer layer includes a reactant that can add to a carbon-carbon double bond to produce substituted carbons joined by a single carbon-carbon bond, wherein the organic polymer layer is adjacent to an additional layer within the memory element, a memory-state transition ensuing when the reactant from the organic polymer layer is driven into the additional layer to restore broken polymer chains to an unbroken state.

14. The organic-polymer-based memory element of claim 1 wherein, in the first memory state, the organic polymer layer exhibits a first electrical resistivity and wherein, in the second memory state, the organic polymer layer exhibits a second electrical resistivity higher than the first resistivity, the organic-polymer-based memory element therefore a fuse-type memory element.

15. The organic-polymer-based memory element of claim 14, wherein a memory-state transition is initiated by applying to the organic-polymer-based memory element one or more state-transition-facilitating agents selected from among:
heating;
cooling;
an electrical voltage potential;
a chemical potential;
an electrochemical potential;
electrical current;
electromagnetic radiation; and
a magnetic field.

16. The organic-polymer-based memory element of claim 15 wherein the organic polymer layer includes dopant chemical entities in addition to organic polymers, the dopant chemical entities inactive in the first memory state and active in the second memory state, a memory-state transition ensuing when the dopant entities within the organic polymer layer are deactivated.

17. The organic-polymer-based memory element of claim 15 wherein the organic polymer layer is adjacent to an additional layer within the memory element, a memory-state transition ensuing when the dopant entities are driven from within the organic polymer layer to the additional layer.

18. The organic-polymer-based memory element of claim 15 wherein organic polymers within the organic polymer layer are aligned, a memory-state transition ensuing when the organic polymers are disordered with respect to one another within the organic polymer layer.

19. The organic-polymer-based memory element of claim 15 wherein the organic polymer layer is adjacent to an additional layer within the memory element that contains cross-linking chemical entities, a memory-state transition ensuing when the cross-linking chemical entities are driven from the additional layer into the organic polymer layer.

20. The organic-polymer-based memory element of claim 15 wherein the organic polymer layer is adjacent to an additional layer within the memory element that contains polymer-chain-breaking chemical entities, a memory-state transition ensuing when the polymer-chain-breaking chemical entities are driven into the organic polymer layer from the additional layer.

21. The organic-polymer-based memory element of claim 15 wherein the organic polymer layer includes cross-linking chemical entities, a memory-state transition ensuing when the cross-linking chemical entities are activated.

22. The organic-polymer-based memory element of claim 15 wherein the organic polymer layer includes polymer-chain-breaking chemical entities, a memory-state transition ensuing when the polymer-chain-breaking chemical entities are activated.

23. The organic-polymer-based memory element of claim 15 wherein the organic polymer layer includes dopant chemical entities and dopant-inhibiting chemical entities in addition to organic polymers, a memory-state transition ensuing when the dopant entities within the organic polymer layer are activated.

24. The organic-polymer-based memory element of claim 15 wherein the organic polymer layer includes dopant chemical entities, wherein the organic polymer layer is adjacent to an additional layer within the memory element, the additional layer including dopant-inhibiting chemical entities, a memory-state transition ensuing when the dopant-inhibiting chemical entities are driven into the organic polymer layer from the additional layer.

25. The organic-polymer-based memory element of claim 15 wherein the organic polymer layer is adjacent to an additional layer within the memory element that includes a reactant that can add to a carbon-carbon double bond to produce substituted carbons joined by a single carbon-carbon bond, a memory-state transition ensuing when the reactant is driven into the organic polymer layer from the additional layer.

26. The organic-polymer-based memory element of claim 1 wherein, upon application of a switch, the memory element irreversibly transitions from the first memory state to the second memory state.

27. The organic-polymer-based memory element of claim 1 wherein, upon application of the switch, the memory element reversibly transitions from a first memory state to a second memory state under, subsequently transitioning back to the first memory state in response to application of a second switch.

28. A two-dimensional memory array fashioned from memory elements of claim 1.

29. An electronic device containing the two-dimensional memory array of claim 28, switching between memory states of the memory elements of the two-dimensional memory array to store data values.

30. A three-dimensional memory array fashioned from memory elements of claim 1.

31. An electronic device containing the two-dimensional memory array of claim 30, switching between memory states of the memory elements of the three-dimensional memory array to store data values.

32. A computer system comprising:
a processor; and
a memory comprising a number of memory elements of claim 1.
